(19) United States
(12) Patent Application Publication
(10) Pub. No.: US 2008/0067604 A1
(43) Pub. Date: Mar. 20, 2008

(54) Field effect transistor arrangement, memory device and methods of forming the same

(76) Inventor: Lars Bach, Ullersdorf (DE)

Correspondence Address: EDELL, SHAPIRO & FINNAN, LLC, 1901 RESEARCH BLVD., SUITE 400, ROCKVILLE, MD, 20850, US

(21) Appl. No.: 11/522,516

(22) Filed: Sep. 18, 2006

(51) Int. Cl. H01L 29/772; H01L 21/8234

(52) U.S. Cl. 257/368; 438/199; 438/275; 257/412

(57) ABSTRACT

Sacrificial structures are provided on a substrate. A template fills a space between the sacrificial structures. The sacrificial structures are removed, where openings are formed in the template. A polysilicon layer is deposited in a single continuous deposition process. First portions of the polysilicon layer fill the openings. A second portion of the polysilicon layer bear on the first portions and the template. The second portion is patterned to form a base layer of a connection line. The first portions that may form gate electrodes and the base layer are provided in a single deposition process without temporarily exposing the upper edges of the first portions and without forming a deposition interface between the first portions and the base layer.

### FIELD OF THE INVENTION

The present invention relates to a method of forming a 3D-polysilicon structure, to field effect transistor arrangements and methods of forming field effect transistor arrangements, and to non-volatile memory devices and methods of forming non-volatile memory devices.

### BACKGROUND

A field effect transistor comprises an active area including a first and a second source/drain region and a channel region separating the first and the second source/drain region. The first and the second source/drain regions are impurity regions of a first conductivity type. The channel region is undoped or of a second conductivity type that is opposite to the first conductivity type. The active area is formed within a single crystalline semiconductor substrate. The field effect transistor further comprises a gate electrode that is separated from the channel region by a gate dielectric. An electrical potential applied to the gate electrode controls the distribution of charge carriers in the channel region such that the channel region may switch between a conductive state and a non-conductive state.

The gate electrode includes of a gate conductor layer material that is usually provided above the semiconductor substrate. Typically, the gate conductor material is heavily doped polycrystalline silicon (polysilicon), because the value of the work function of polysilicon fulfils the requirements for controlling the charge carrier distribution in the channel region in a suitable way.

The gate electrodes are connected to further electronic devices on the semiconductor substrate via connection lines. The preferred material for the connection lines is a material with low electrical resistance, as for example a metal or a conductive metal compound. The connection lines bear first on the gate electrodes associated to the respective connection line and second on an insulating template material surrounding the gate electrodes. Usually, each connection line comprises a base layer bearing or disposed on the associated gate electrodes and that portions of the insulating template that separate the gate electrodes associated with the connection line. Usually the base layer consists of the gate conductor material.

According to a conventional method of manufacturing a field effect transistor arrangement, gate electrodes are provided on the semiconductor substrate. The space between the gate electrodes is filled with an insulating fill material. Then a layer stack is deposited that comprises the base layer, a high conductivity layer and an insulating cap layer. The layer stack is patterned to form the connection lines. Before deposition of the layer stack, the gate conductor material of the gate electrodes is exposed for a while. The exposed gate conductor material is highly sensitive to contamination. Contamination of the exposed gate conductor material may result in the formation of long whisker structures that may result in serious damages in the associated regions of the substrate.

Further, a deposition interface may be generated between the gate conductor material of the gate electrode and the gate conductor material of the base layer. The deposition interface may result from slightly different deposition conditions or from chemical activity on the surface of the gate electrode during the time the gate electrode is exposed. The deposition interface may deteriorate the electrical connection between the base layer of the connection line and the gate electrode.

Therefore, a need exists to simplify the method of forming 3D-polysilicon structures, as for example a 3D-polysilicon structure comprising a gate electrode portion and a connection line portion. There is also a need to improve the properties of 3D-polysilicon structures, such as structures comprising gate electrodes and a base layer of a connection line.

### SUMMARY

In an exemplary embodiment, the invention provides a method of forming a 3D-polysilicon structure that comprises providing a sacrificial layer above a semiconductor substrate and then patterning the sacrificial layer to form a sacrificial structure. A template section of the semiconductor substrate is exposed, wherein the template section surrounds the sacrificial structure. A template is formed on the template section of the semiconductor substrate. The sacrificial structure is removed to form an opening in the template. In a single deposition step, a polysilicon layer comprising a bottom portion and a top portion is deposited, wherein the bottom portion fills the opening and forms a lower polysilicon structure and wherein the top portion bears on the lower polysilicon structure and the template. The top portion is patterned to form the 3D-polysilicon structure that is homogeneous and without deposition interface between the bottom portion and the top portion.

In another exemplary embodiment, the invention provides a method of forming a field effect transistor arrangement. A sacrificial layer is disposed on a semiconductor substrate. The sacrificial layer is patterned to form sacrificial structures having an upper edge, wherein the sacrificial structures are separated by a space. A template is provided that fills the space and leaves the upper edge of the sacrificial structures exposed. The sacrificial structures are removed to form openings in the template. In a single deposition step, a polysilicon layer comprising bottom portions and a top portion is deposited, wherein the bottom portions fill the openings to form in each case a gate electrode. The top portion bears on the gate electrodes and on the template. The top portion is patterned to form a connection line bearing or disposed on the gate electrodes and on sections of the template, wherein the connection line is a homogeneous structure without deposition interface between the gate electrodes and the connection line.

In a further exemplary embodiment, the invention provides a method of forming a non-volatile memory device. A storage layer stack is disposed on a semiconductor substrate. A sacrificial layer is disposed on the storage layer stack. The sacrificial layer is patterned to form sacrificial structures having an upper edge, wherein the sacrificial structures are separated by a space. A template is provided that fills the space and leaves the upper edge of the sacrificial structures exposed. The sacrificial structures are removed to form openings in the template. In a single deposition step, a polysilicon layer is deposited that comprises bottom portions and a top portion. The bottom portions fill the openings to form in each case a control gate. The top portion bears on the control gates and on the template. The top portion is patterned to form a base layer of a word line that bears on the control gates and on sections of the template. The base layer and the control gates form a homogeneous structure without deposition interface between the control gates and the base layer.

In a further embodiment, the invention provides a further method of forming a memory device including a memory cell array section and a bit line contact section. In the memory cell array section, memory cells are provided that are connected to bit lines buried in a semiconductor substrate. In the bit line contact section, temporary structures are provided that are disposed above the semiconductor substrate and that cover the buried bit lines. Template spacers are provided that cover in each case a vertical sidewall of the temporary structures. The temporary structures are removed by a fluid that also dissolves the template spacers.

In yet a further embodiment, the invention provides a field effect transistor arrangement that comprises gate electrodes being arranged over a pattern surface of a semiconductor substrate and including a gate conductor material. A connection line connects the gate electrodes and comprises a base layer including the gate conductor material. The connection line bears in sections on the gate electrodes. The gate conductor material of the base layer and of the gate electrode structures forms a single homogeneous structure without deposition interface between the gate electrode and the base layer.

In still another embodiment, the invention provides a non-volatile memory device comprising control gates that are arranged over a pattern surface of a semiconductor substrate. The control gates includes a gate conductor material. A word line connects the control gates and comprises a base layer including the gate conductor material. The word line bears in sections on the control gates. The gate conductor material of the base layer and of the control gates forms a single homogenous structure without deposition interface between the control gates and the base layer.

These and still further objects and advantages of the present invention will become apparent upon consideration of the following definitions, descriptions and descriptive figures of exemplary embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

FIGS. 1A to 1G illustrate a method of forming a memory cell array comprising non-volatile memory cells, in which cross-sectional views of a section of the memory cell array are depicted in different stages of processing according to an exemplary embodiment of the invention.

FIGS. 2A to 2B illustrate a method of forming field effect transistors, in which cross-sectional views of a substrate are depicted in different stages of processing according to another exemplary embodiment of the invention.

FIGS. 3A to 3D are cross-sectional views of a section of a memory device processed according to a further exemplary embodiment of the invention after providing a template spacer liner.

FIGS. 4A to 4D are cross-sectional views of a section of a memory device processed according to the exemplary embodiment of FIG. 3 after providing a CMOS spacer layer.

FIGS. 5A to 5D are cross-sectional views of a section of a memory device processed according to the exemplary embodiment of FIG. 3 after forming CMOS spacers.

FIGS. 6A to 6D are cross-sectional views of a section of a memory device processed according to the exemplary embodiment of FIG. 3 after forming template spacers.

FIGS. 7A to 7D are cross-sectional views of a section of a memory device processed according to the exemplary embodiment of FIG. 3 after depositing an interlayer dielectric.

FIG. 8 is a cross-sectional view of a section of a memory device processed according to the exemplary embodiment of FIG. 3 after forming contact openings.

FIG. 9 is a cross-sectional view of a memory device processed according to a conventional method after forming contact openings.

### DETAILED DESCRIPTION

In the following description, the term 3D-polysilicon structure refers to a polysilicon structure including a bottom layer with a first pattern and a top layer bearing or disposed on the bottom layer and with a second pattern that is different from the first pattern and overhanging the bottom layer laterally.

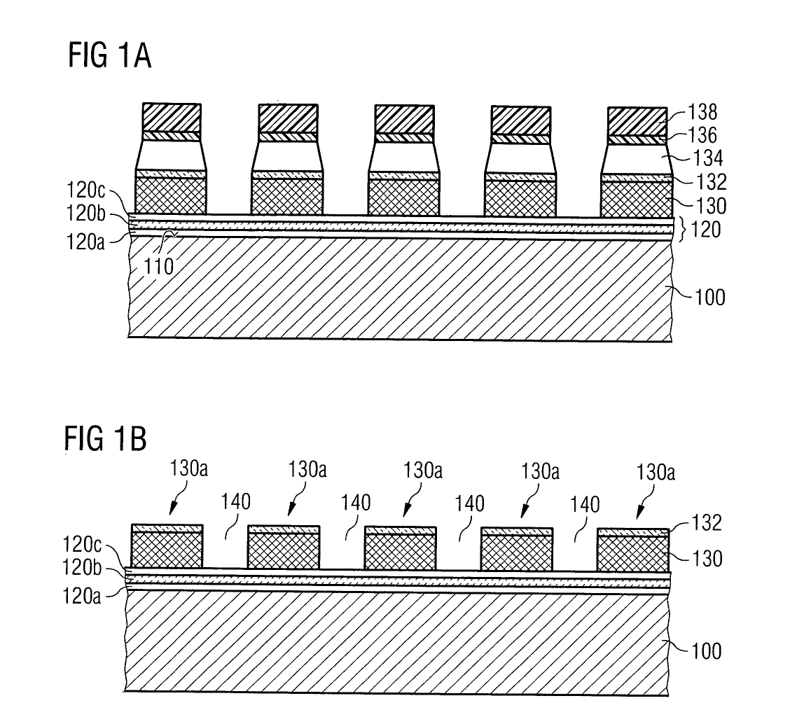

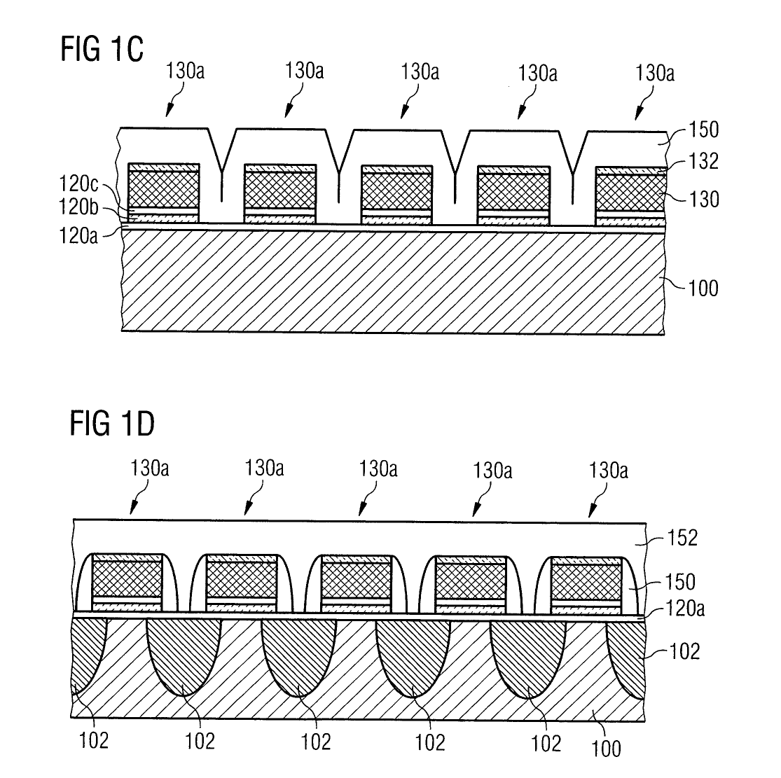

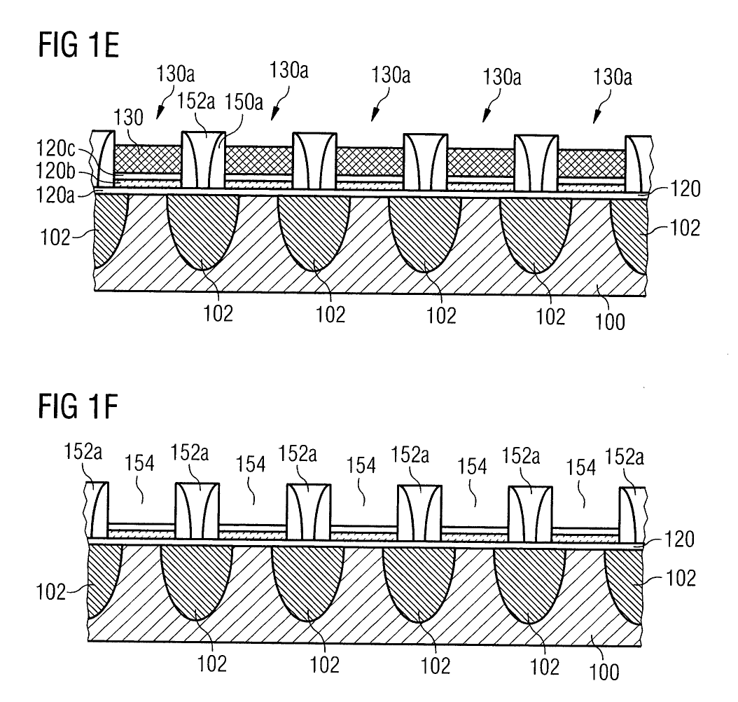

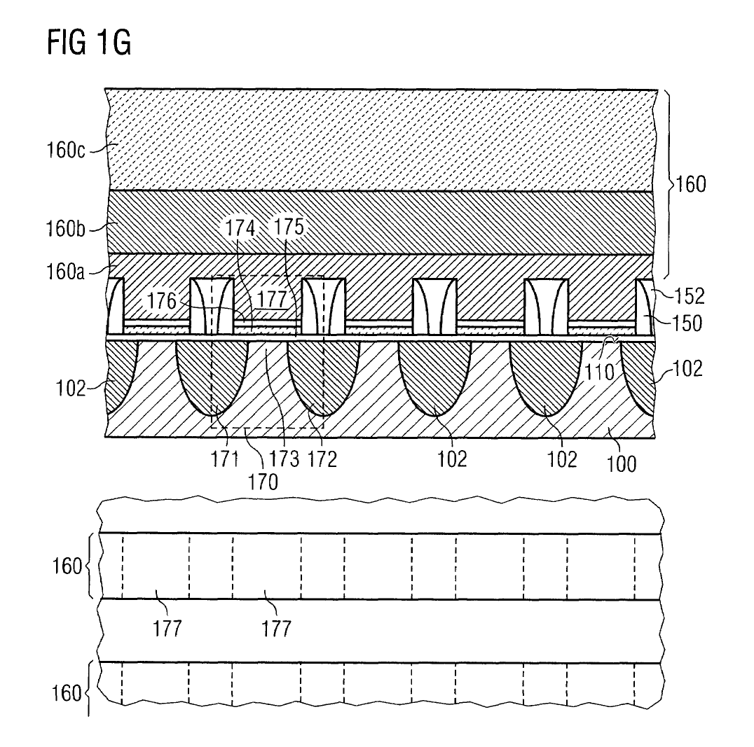

FIGS. 1A to 1G illustrate a method of forming a 3D-polysilicon structure, wherein the 3D-polysilicon structure comprises a bottom portion forming a plurality of control gates of non-volatile memory cells and a top portion forming a base layer of a word line. In the following, the method of forming the 3D-polysilicon structures is described in terms corresponding to a method of forming a non-volatile memory device but not limiting the method to this application.

The term semiconductor substrate, as used herein, is understood to include semiconductor wafers. The term semiconductor substrate is also used herein to refer to semiconductor structures during processing and may include other layers that have previously been fabricated. The semiconductor substrate may comprise doped and undoped sections, epitaxial semiconductor layers supported by a base semiconductor or a base insulator, as well as other semiconductor structures.

FIG. 1A is a cross-section of a section of a semiconductor substrate 100 according to an exemplary embodiment of the invention. The illustrated upper portion of the semiconductor substrate 100 may be lightly p-doped. A storage layer stack 120 is provided on a pattern surface 110 of the semiconductor substrate 100. The storage layer stack 120 comprises a bottom barrier layer 120a bearing or disposed on the substrate 100, a storage layer 120b covering the bottom barrier layer 120a and a top barrier layer 120c covering the storage layer 120b. The top and the bottom barrier layers may have a thickness of about 2 to 10 nanometers and may be silicon oxide layers. The storage layer 120b may be a dielectric layer, such as a silicon nitride layer, or a conductive layer, such as a polysilicon layer. The thickness of the storage layer 120b may be 5 to 10 nanometers. A sacrificial layer 130 is deposited on the storage layer stack 120. The sacrificial layer 130 has, for example, a thickness of about 10 to 100 nanometers. The sacrificial layer 130 may be a carbon layer. According to an exemplary embodiment, the carbon layer is an amorphous carbon layer and 40 to 50 nanometers thick. The carbon layer may be deposited by a PECVD process, wherein acetylene C₂H₂, ethylene C₂H₄, propane C₂H₆ or another suitable carbon-hydroxide compound is supplied at a temperature between 250° C. and 550° C. In one embodiment, propene C₃H₆ is supplied at a temperature of about 400° C. The supply rate may range from 500 to 3000 sccm. In one embodiment, the supply rate is 2000 sccm. Further, an inert gaseous fluid, for example He, Ar, N₂ may be supplied with a rate of 500 to 5000 sccm. In one embodiment, He is supplied with a rate of 700 sccm. The ambient pressure may range from 3 to 8 Torr and the power of the plasma may range from 800 to 2000 W. In one embodiment, the ambient pressure is about 5.5 Torr and the plasma power is about 1600 W.

An etch stop layer 132 may be deposited on the sacrificial layer 130. The etch stop layer 132 may be a silicon nitride liner and may have a thickness of 6 to 20 nanometers, for example 10 nanometers. A mask layer 134 is deposited on the etch stop layer 132. In an exemplary embodiment, the mask layer 134 is a silicon oxynitride layer, the thickness of which may be selected such that the mask layer 134 is completely consumed during following steps of patterning the sacrificial layer 130 and/or the storage layer stack 120. In one embodiment, the mask layer 134 may have a thickness of about 20 to 60 nanometers. The etch stop layer 132 may protect a carbon sacrificial layer 130 from being oxidized during deposition of the mask layer 134. A first resist layer 136 and a second 138 resist layer of a bi-layer resist system comprising an imaging layer and an antireflective coating may be deposited on the mask layer 134. The resist layers 136, 138 are patterned by photolithographic techniques to form a plurality of parallel, line-shaped stripes extending in a direction that is perpendicular to the cross-sectional plane. The pattern of the resist layer 136, 138 is etched first into mask layer 134 and then into sacrificial layer 130. A plasma etch may be used to pattern the sacrificial layer 130. The plasma etch may be performed with a pressure from 300 to 1000 mTorr, for example 550 mTorr, an oxygen flow rate of 4000 to 10000 sccm, for example 7000 sccm, a N₂ flow rate of 100 to 400 sccm, for example 200 sccm, and a temperature from 200 to 400° C., for example 250° C. The plasma power may be about 2000 W.

FIG. 1A shows the storage layer stack 120 covering the pattern surface 110 of the semiconductor substrate 100. Above the storage layer stack 120, line-shaped stripes extend in a direction perpendicular to the cross-sectional plane. Each stripe may comprise a portion of the sacrificial layer 130, the etch stop layer 132, the mask layer 134 and the resist layers 136, 138. The sidewalls of the mask layer sections 134 are oblique and narrow the space between adjacent stripes. The sections of the sacrificial layer 130 show vertical sidewalls due to the etch properties of amorphous carbon.

Referring to FIG. 1B, the remaining portions of the resist layers 136, 138 may be removed. With the remnant sections of the sacrificial layer 130 as etch mask, the top barrier layer 120c and the storage layer 120b of the storage layer stack 120 may be patterned, wherein the mask layer 134 may be consumed. In case of a silicon nitride liner as storage layer 120b, the mask layer 134 protects etch stop layer 132 during patterning of the storage layer 120b. The bottom barrier layer 120a may be etched in the exposed sections during removal of the mask layer 134. A sacrificial silicon oxide may be grown in the exposed sections of semiconductor substrate 100.

FIG. 1B shows line-shaped sacrificial structures 130a that are arranged parallel to each other and extend in a direction that is perpendicular to the cross-sectional plane. Each sacrificial structure 130a comprises a portion of bottom barrier layer 120a, of storage layer 120b, and of top barrier layer 120c and a section of sacrificial layer 130 that is covered by a section of etch stop layer 132. The sacrificial structures 130a are separated by spaces 140 that expose in each case a template section of semiconductor substrate 100, wherein the semiconductor substrate 100 may be covered by a sacrificial oxide or residues of bottom barrier layer 120a in the template sections.

With regard to FIG. 1C, a spacer layer 150 may be deposited. The spacer layer 150 may be a silicon oxide layer that is deposited by a conformal LPCVD process. In one embodiment, the thickness of the spacer layer 150 is about half the distance of the sacrificial structure 130a. FIG. 1C shows the conformal spacer layer 150 covering the sacrificial structures 130a.

With regard to FIGS. 1D and 1E, the spacer layer 150 is etched anisotropically to form spacers 150a extending along the vertical sidewalls of the sacrificial structures 130a. Sections of the spacer layer 150 that cover the etch stop layer 132 are removed. An implantation step is performed, wherein the sacrificial structure 130a and the spacers 150a act as an implantation mask shielding the underlying portions of semiconductor substrate 100 against the implant ions. A template layer 152 is deposited on the sacrificial structures 130a. The template layer 152 may be a silicon oxide layer that is deposited by an HARP process.

FIGS. 1D and 1E show the spacers 150a extending along the vertical sidewalls of sacrificial structures 130a. Within semiconductor substrate 100, which may be lightly p-doped, heavily n-doped buried bit lines 102 may be formed. The template layer 152 covers the sacrificial structures 130a and fills the spaces 140 between them above the template sections.

With regard to FIG. 1E, the template layer 152 is recessed by a chemical mechanical polishing step which stops on the upper edge of etch stop layer 132. The etch stop layer 132 can be removed by using a hot phosphoric acid. A deglaze and various clean steps may be performed.

FIG. 1E illustrates exposed sacrificial structures 130a that are embedded in a template 152a that results from polishing the template layer 152. The etch stop liner 132 is removed. The upper edges of the sacrificial structures 130a are exposed.

Referring to FIG. 1F, the sacrificial structures 130a are removed by ashing the carbon in a plasma etch process using, for example, a mixture of CF₄ and oxygen, wherein He is used as stabilizer.

As can be seen in FIG. 1F, the removal of the sacrificial structure 130a leaves openings 154 between the template sections 152a. The carbon recess process is highly selective to silicon oxide, such that the storage layer stack 120 comprising the top barrier layer 120c and the storage layer 120b is not affected. The carbon may be removed quickly compared to a sacrificial polysilicon liner, the removal of which would last at least a few hours.

With reference to FIG. 1G, a further clean step may be performed to avoid contamination of the top barrier layer 120c. A base layer 160a is deposited. The base layer 160a is, according to an exemplary embodiment, heavily doped polysilicon. The thickness of the base layer is between 40 to 200 nm. A high conductivity layer 160b is deposited on the base layer 160a. The high conductivity layer 160b may comprise a metal layer or a conductive metal compound layer and various adhesive and diffusion barrier layers. An insulating cap layer 160c is disposed on the high conductivity layer 160b. The cap layer 160c may be a silicon nitride layer and may have a thickness of about 50 to 200 nm. The base layer 160a, the conductivity layer 160b and the cap layer 160c are patterned to form word lines 160 extending in a direction that is perpendicular to the bit line direction.

The upper half of FIG. 1G shows a cross-sectional view of a memory device comprising non-volatile memory cells 170. The lower portion of FIG. 1G shows the same structure in a top view. Each memory cell 170 comprises an active area including a first impurity region 171 and a second 172 impurity region. The first and the second impurity regions 171, 172 are n-conductive. A channel region 173 separating the first impurity region 171 and the second impurity region 172 is p-conductive. The charge carrier distribution within channel region 173 depends on a charge stored within the storage film 174 and an electrical potential applied to the control gate 177. Bottom barrier film 175 separates storage film 174 from the channel region 173. A top barrier film 176 separates the control gate 177 and the storage film 174. The first impurity region 171 and the second impurity region 172 of the memory cell 170 are in each case part of a buried bit line 102 extending in a bit line direction that is perpendicular to the cross-sectional plane. A word line 160 extends along a word line direction intersecting the bit line direction. The word line direction may be perpendicular to the bit line direction. The word line 160 comprises a base layer 160a, a high conductivity layer 160b disposed on the base layer 160a and a cap layer 160c disposed on the conductivity layer 160b.

The base layer 160a bears on the control gates 177 and on sections of the template 152a. The base layer 160a and the control gates 177 are formed from a gate conductor material that is deposited in one continuous step. The gate conductor material is polysilicon that may be heavily doped. Contrary to conventional methods, a fictitious upper edge of the control gate 177 is not exposed to other conditions than the conditions occurring during the continuous deposition process. The formation of a deposition interface between the control gate section and the base layer section of the gate conductor material is avoided. The growth of whiskers on the control gate section and deposition interface issues are avoided.

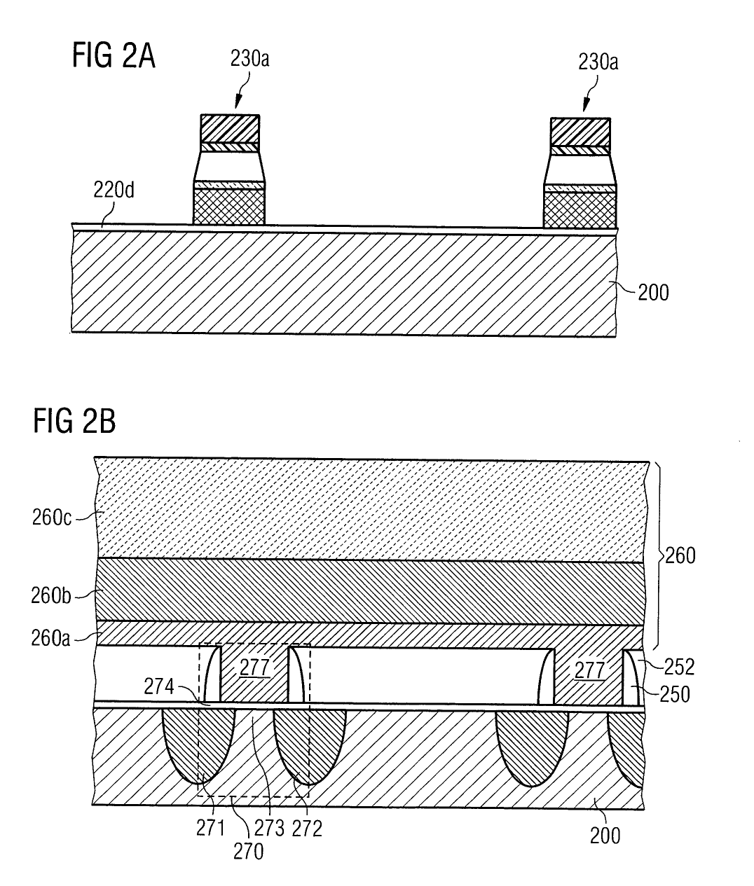

FIGS. 2A to 2B depict a field effect transistor arrangement and a method of forming the same. The method differs from the method as described in FIGS. 1A to 1G in that, instead of a storage layer stack 120, a simple gate dielectric 220d is provided on the pattern surface 110. The arrangement of the field effect transistors may follow other design rules. Instead of memory cells 170 according to FIG. 1G, a plurality of field effect transistors 270 is formed. Further, instead of buried bit lines connecting the first and second impurity regions, contact structures (not shown) may be formed in a plane parallel to the cross-sectional plan to connect the impurity regions of the field effect transistors 270.

Each field-effect transistor 270 comprises an active area including a source region 271 and a drain 272 region. The source 271 and the drain 272 regions may be n-conductive. A channel region 273 separating the source and the drain regions 271, 272 may be p-conductive. The charge carrier distribution within channel region 273 depends on an electrical potential applied to a gate electrode 277. A gate dielectric film 274 separates the gate electrode 277 and the channel region 273. A word line 260 extends along a word line direction. The word line 260 comprises a base layer 260a, a high conductivity layer 260b disposed on the base layer 260a and a cap layer 260c disposed on the high conductivity layer 260b.

The base layer 260a bears on or is adjacent the gate electrode 277 and also sections of a template 252. The template 252 corresponds to that of FIGS. 1A-1G. The base layer 160a and the adjoining gate electrode 277 are formed from a gate conductor material that is deposited in one continuous step. The gate conductor material may be polysilicon that may be heavily doped. Contrary to conventional methods, a fictitious upper edge of the gate electrode 277 is not exposed to other conditions than the conditions occurring during the continuous deposition process.

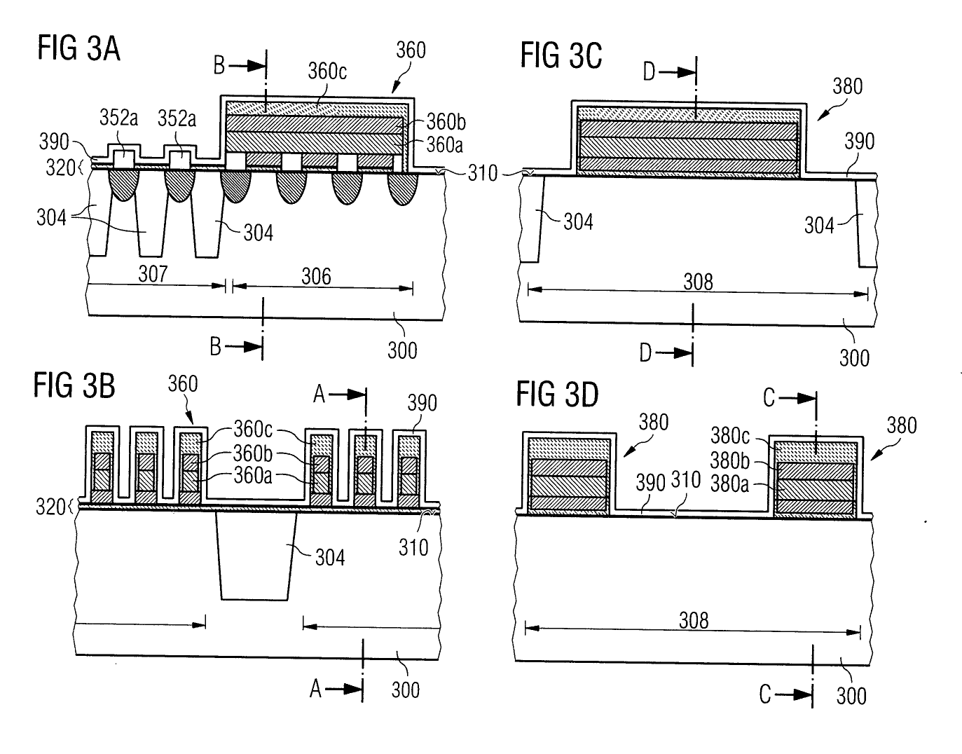

FIGS. 3 to 9 depict a method of forming bit line contacts of a non-volatile memory device. FIGS. 3 to 7 illustrate in each case four cross-sectional views of a non-volatile memory device comprising a memory cell array section 306, a bit line contact section 307, and a CMOS section 308. The Figs. denominated by “A” refer in each case to cross-sections of the memory cell array section 306 and the bit line contact section 307 along a word line direction and the Figs. denominated by “B” to a cross-section along a bit line direction that is perpendicular to the word line direction. The Figs. denominated by “C” and “D” refer to two cross-sections of the CMOS section 308 that are perpendicular to each other.

Referring to FIGS. 3A to 3D, word lines 360 comprising a base layer 360a, a high conductivity layer 360b disposed on the base layer 360a, and an insulating cap layer 360c disposed on the high conductivity layer 360b are formed in the memory cell array section 306 of a semiconductor substrate 300. Within the semiconductor substrate 300 that may be a single crystalline silicon wafer buried bit lines 302 are formed as n-doped impurity regions. The bit lines 302 extend along the bit line direction that may be perpendicular to the word line direction. The bit lines 302 extend between the memory cell array section 306 and a bit line contact section 307 of the semiconductor substrate 300. Within the bit line contact section 307, neighboring bit lines 302 are separated by shallow isolation structures 304. FIG. 3 may follow from the structure as illustrated in FIG. 1G, wherein patterning of the word lines 360 comprises removal of the word lines 360 in the bit line contact sections 307, such that a template 352a, which may be a silicon oxide template, is exposed in the bit line contact section 307.

In a CMOS section 308 of substrate 300, CMOS gate electrodes 380 are formed. The CMOS gate electrodes 380 comprise in each case a base layer 380a, a high conductivity layer 380b disposed on the base layer 380a and a dielectric layer 380c disposed on the high conductivity layer 380b that may correspond to the layers of the word lines 360. A conformal template spacer liner 390 is deposited. The template spacer liner 390 may have a thickness of about 10 nm. In an exemplary embodiment, the template spacer liner 390 is deposited via a LPCVD process. The template spacer liner 390 may be solvable by a fluid, for example a solvent, that also dissolves the template 352a. The template in the bit line contact section 307 forms temporary structures 352a. FIG. 3A shows the template spacer liner 390 covering the temporary structures 352a, the word lines 360, and the CMOS gate electrodes 380.

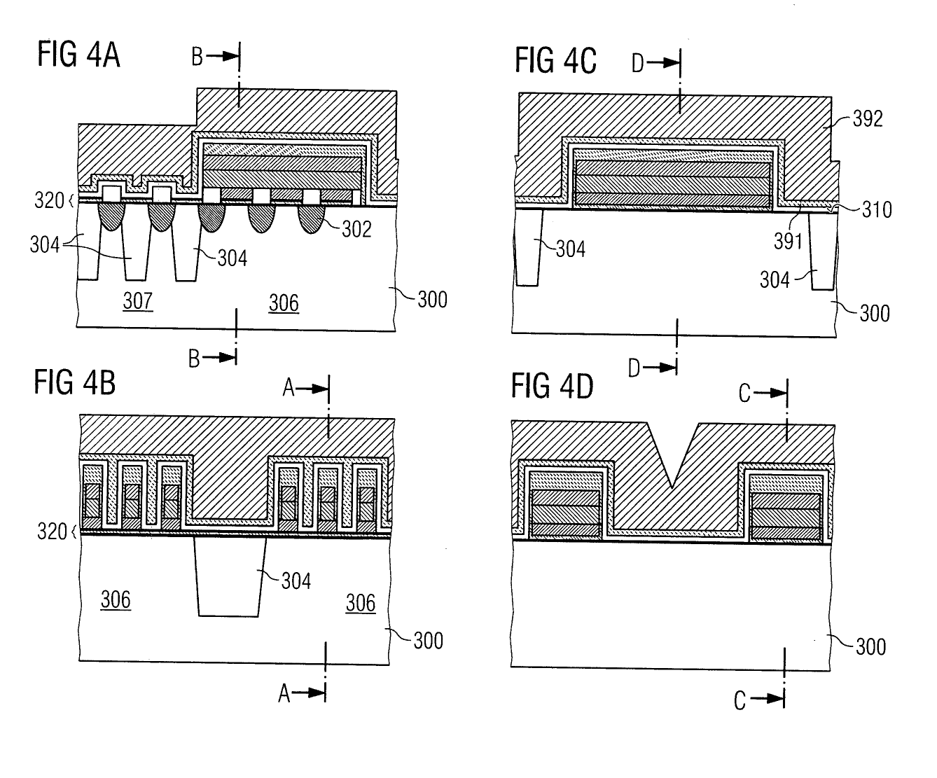

With regard to FIGS. 4A to 4D, a CMOS spacer liner 391 is deposited on the template spacer liner 390 and a CMOS spacer layer 392 is deposited on the CMOS spacer liner 391.

FIGS. 4A to 4D illustrate the CMOS spacer liner 391 covering the template spacer liner 390 and the CMOS spacer layer 392 covering the CMOS spacer liner 391. The CMOS spacer liner 391 may be deposited by a LPCVD process in a conformal manner. In one embodiment, the CMOS spacer liner 391 is a silicon nitride liner having a thickness of 5 to 15 nanometers. The CMOS spacer layer 392 may have a thickness of 50 to 200 nanometers. In one embodiment, the CMOS spacer layer 392 is a conformal polysilicon layer.

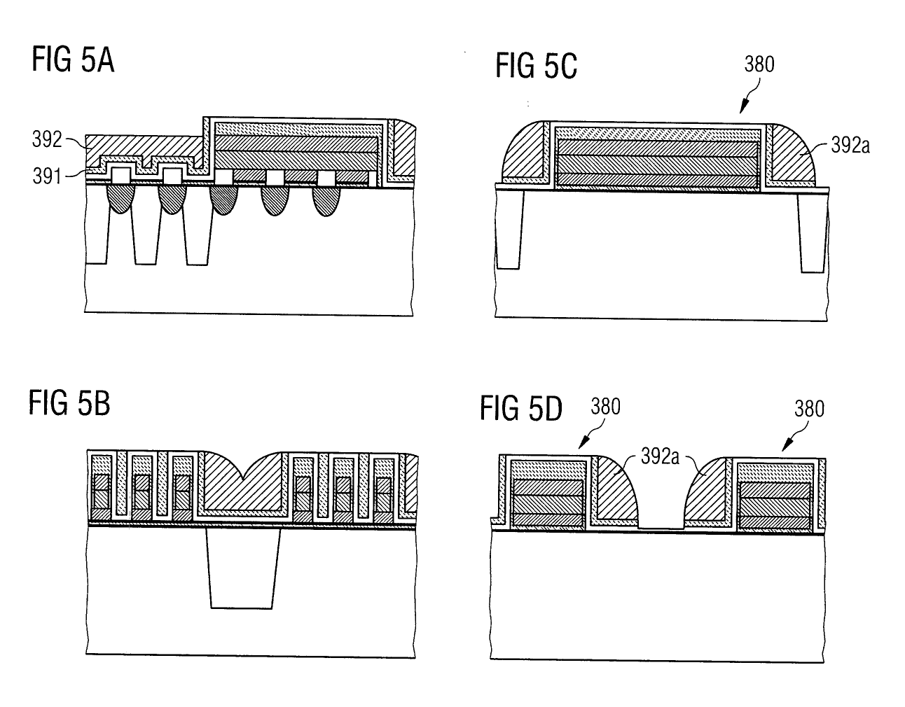

Referring to FIGS. 5A to 5D, an anisotropical etch is performed to form CMOS spacers 392a from the CMOS spacer layer 392 and the CMOS spacer liner 391.

FIGS. 5A to 5D show the CMOS spacers 392a extending along the vertical sidewalls of the CMOS gate electrodes 380. The width of the CMOS spacers 392a is adjusted by the parameters of the etch of the CMOS spacer layer 392. The etched CMOS spacer layer 392 acts as etch mask in course of the etch of CMOS spacer liner 391. Template spacer liner 390 acts as etch stop during recess of the CMOS spacer liner 391. An implantation step may be performed, wherein in the CMOS section 308 impurity regions are formed in a distance to the CMOS gate electrodes 380 that is adjusted by the width of the CMOS spacers 392a.

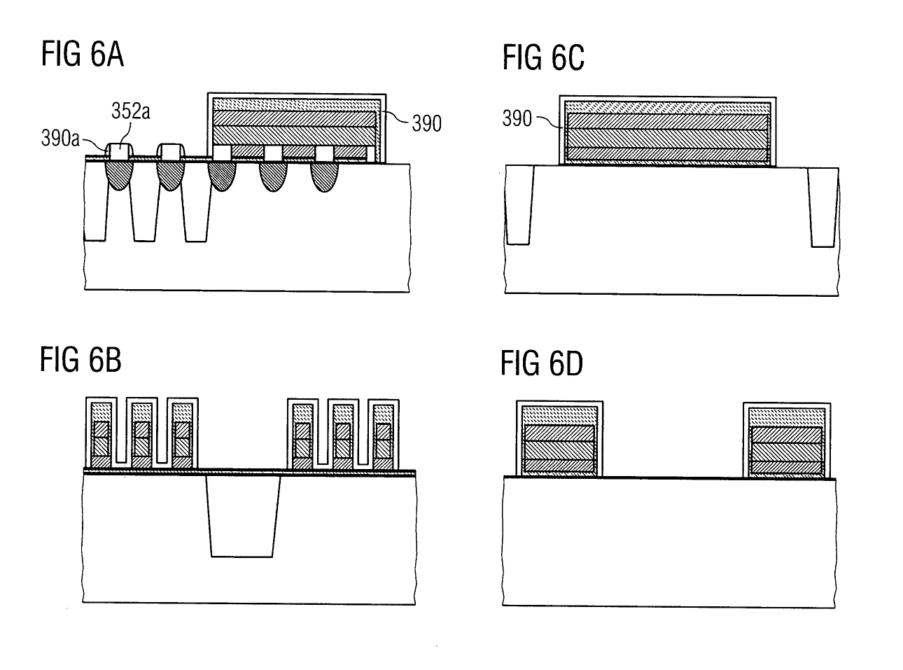

Referring to FIGS. 6A to 6D, the CMOS spacers 392a are removed by an etch of the polysilicon that is selective against the silicon oxide of the template spacer liner 390. The CMOS spacer liner 391 may be removed by using hot phosphoric acid. Then an anisotropic spacer etch may be performed to form template spacers 390a extending along the vertical sidewalls of the temporary structures 352a.

FIGS. 6A to 6D show the template spacers 390a encapsulating the temporary structures 352a in the bit line contact section 307. An upper edge of the temporary structures 352a is exposed. Further sections of template spacer liner 390 cover the word lines 390 in the memory cell array section 306 and the CMOS gate electrodes 380 in the CMOS section 309.

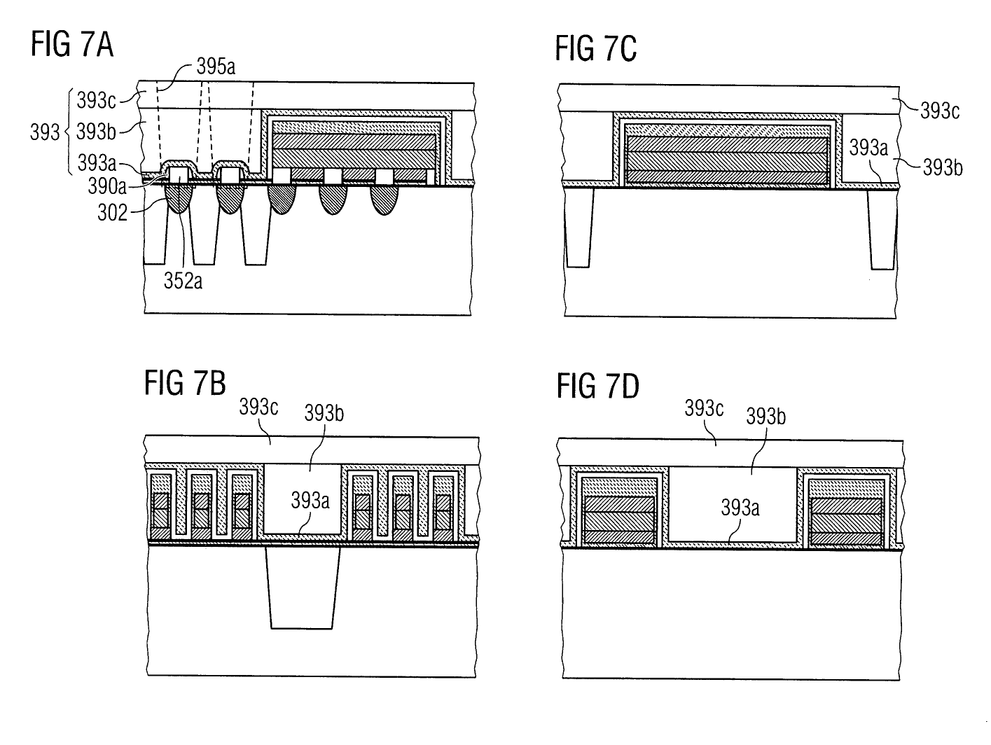

With regard to FIGS. 7A to 7D, a barrier liner 393a may be deposited. A fill layer 393b may be deposited that fills the space between the word lines 360 and the CMOS gate electrodes 380. A chemical mechanical polishing step may be performed that stops on the barrier layer or the cap layer of word lines 360 and CMOS gate electrodes 380. A spacer layer 393c may be deposited on the planarized topology and contact openings 395 are provided in the interlayer dielectric 393 formed from barrier liner 393a, fill layer 393b, and spacer layer 393c.

FIGS. 7A to 7D illustrate the interlayer dielectric 393 filling the spaces between the temporary structures 352a, word lines 360, and CMOS gate electrodes 380 and decoupling capacitively the CMOS gate electrodes 380 and the word lines 360 from further conductive structures (not shown) that may be provided. FIG. 7A further shows a projection 395a of contact openings as dotted lines. During an etch of the interlayer dielectric 393, the areas within the dotted lines are exposed to the etching fluid. The etch process exposing the buried bit lines 302, exposes first the barrier layer 393a, then the temporary structures 352a including the template spacer 390a and then, after removing the temporary structures 352a, the buried bit line structures 302.

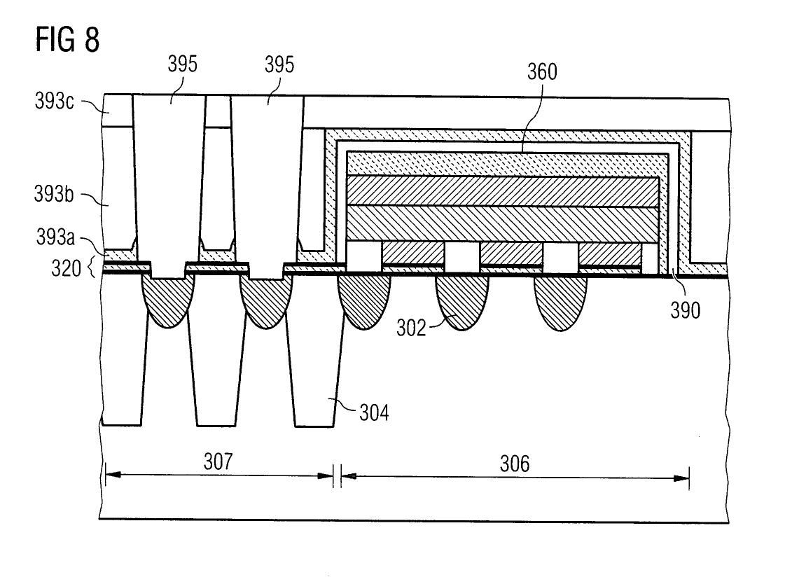

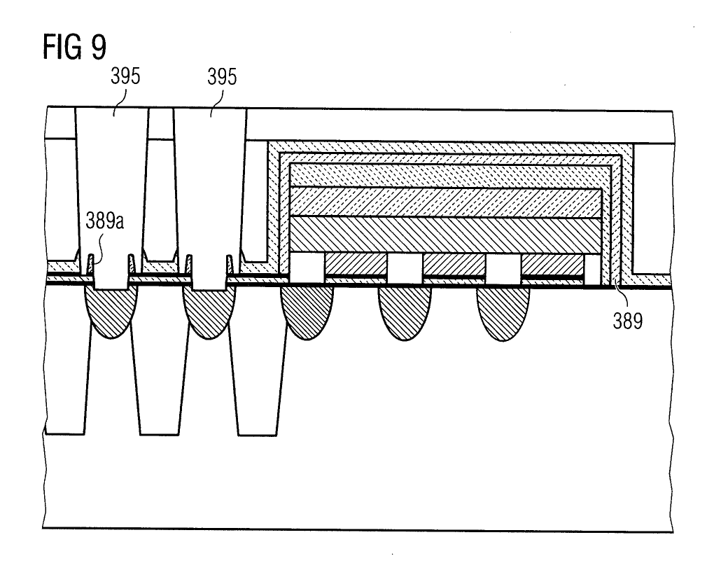

As illustrated in FIG. 8, during formation of the contact openings 395 both the temporary structures 352a and the template spacer 390a are removed as they are both dissolvable in the same etching fluid. In conventional methods providing a template spacer liner 389, for example from silicon nitride, spikes 389a resulting from the silicon nitride template spacer liner may remain in the contact openings 395, as illustrated in FIG. 9. These spikes 389a may collapse during formation of the contact openings 395 or in further course of the process, for example during a fill of the contact openings 395 with a fill material to form bit line contact structures (not shown). Due to the dielectric character of the spikes 389a, fractions of the spikes 389a may increase the resistance between the buried bit line structure 302 and the associated bit line contact structure (not shown).

The fill layer 393b may be a BPSG layer. The spacer layer 393c may be silicon dioxide resulting from the decomposition of tetra ethylene ortho silicate (TEOS). The base layer 393a may be a silicon oxynitride layer that is effective as etch stop layer during the etch of fill layer 393b and spacer layer 393c. The etch chemistry may then be switched to a silicon nitride etch that may stop on the temporary oxide structures 352a or, in case of a misalignment of the contact openings 395, on top of storage layer stack 320. In case of a misalignment, a following oxide etch stops on the nitride layer of the storage layer stack 320.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SIGNS

100 semiconductor substrate
102 buried connection line
110 pattern surface
120 storage layer stack
120a bottom barrier layer
120b storage layer
120c top barrier layer
130 sacrificial layer
130a sacrificial structure
131 recess
132 etch stop layer
134 mask layer
136 resist layer
138 resist layer
140 space, template section
150 spacer layer
150a spacer
152 template layer
152a template
154 opening
160 word line
160a base layer
160b high conductivity layer
160c cap layer
170 memory cell
171 first junction
172 second junction
173 channel region
174 storage film
175 bottom barrier film
176 top barrier film
177 control gate
220d gate dielectric layer
260 connection line
260a base layer
260b high conductivity layer
260c cap layer
270 field effect transistor
271 first source/drain region
272 second source/drain region
273 channel region 274 gate dielectric film
277 gate electrode
300 substrate
302 buried bit line
304 shallow isolation structure
306 memory cell array section
307 bit line contact section
308 CMOS section
310 pattern surface
320 storage layer stack
352a template
360 word line
360a base layer
360b conductivity layer
360c cap layer
380 CMOS gate electrode
380a base layer
380b conductivity layer
380c cap layer
389 template spacer liner
389a spike
390 template spacer liner
390a template spacer
391 CMOS spacer liner
392 CMOS spacer layer
392a CMOS spacer
393 interlayer dielectric
393a barrier liner
393b fill layer
393c spacer layer
395 contact opening
395a contact opening projection

What is claimed:

1. A method of forming a 3D-polysilicon structure, the method comprising:
(a) providing a sacrificial layer above a semiconductor substrate;
(b) patterning the sacrificial layer to form a sacrificial structure, wherein a template section of the semiconductor substrate is exposed, the template section surrounding the sacrificial structure;
(c) forming a template on the template section;
(d) removing the sacrificial structure to form an opening in the template;
(e) depositing a polysilicon layer comprising a bottom portion and a top portion, the bottom portion filling the opening to form a lower polysilicon structure and the top portion being disposed on the lower polysilicon structure and the template; and
(f) patterning the top portion to form the 3D-polysilicon structure, the 3D-polysilicon structure including sections disposed on the template and being homogenous without a deposition interface existing between the bottom portion and the top portion.

2. The method of claim 1, wherein the sacrificial layer comprises an amorphous carbon layer.

3. The method of claim 1, wherein step (c) further comprises:
depositing a template layer that covers the template section and the sacrificial structure; and
recessing the template layer to expose an upper edge of the sacrificial structure.

4. A method of forming a field effect transistor arrangement, comprising:
(a) disposing a sacrificial layer over a semiconductor substrate;
(b) patterning the sacrificial layer to form sacrificial structures including an upper edge, the sacrificial structures being separated by a space;
(c) providing a template filling the space and leaving the upper edge of the sacrificial structures exposed;
(d) removing the sacrificial structures to form openings in the template;
(e) depositing a polysilicon layer comprising bottom portions and a top portion, the bottom portions filling the openings so as to form a gate electrode in each opening with the top portion being disposed on the gate electrodes and on the template; and
(f) patterning the top portion to form a connection line disposed on the gate electrodes and on sections of the template, the connection line and the gate electrodes forming a single homogenous structure without a deposition interface existing between the gate electrode and the connection line.

5. The method of claim 4, wherein the sacrificial layer comprises a carbon layer.

6. The method of claim 4, further comprising, before step (b):
providing an etch stop layer on top of the sacrificial layer, wherein an upper edge of the etch stop layer forms the upper edge of the sacrificial structures.

7. The method of claim 4, wherein step (c) further comprises:
depositing a template layer; and
removing portions of the template layer above the upper edge of the sacrificial structures to form the template.

8. The method of claim 4, further comprising, before step (c):
forming spacer structures extending along vertical sidewalls of the sacrificial structures.

9. The method of claim 8, wherein forming the spacer structures comprises:
depositing a conformal spacer layer; and
performing an anisotropical etch to form the spacer structures from the spacer layer.

10. The method of claim 8, further comprising, before step (c):
performing an implantation step to form buried source/drain regions in the semiconductor substrate and adjacent to the sacrificial structures, wherein the sacrificial structures and the spacer structures comprise an implantation mask.

11. The method of claim 4, further comprising, before step (a):
providing a gate dielectric layer on the semiconductor substrate, wherein the sacrificial layer is provided on the gate dielectric layer.

12. A method of forming a non-volatile memory device, the method comprising:
(a) disposing a storage layer stack on a semiconductor substrate;
(b) disposing a sacrificial layer on the storage layer stack;
(c) patterning the sacrificial layer to form sacrificial structures including an upper edge, the sacrificial structures being separated by spaces;
(d) providing a template filling the spaces and leaving the upper edge of the sacrificial structures exposed;
(e) removing the sacrificial structures to form openings in the template;
(f) depositing a polysilicon layer comprising bottom portions and a top portion, the bottom portions filling the openings to form a control gate in each of the openings and the top portion being disposed on the control gates and the template; and
(g) patterning the top portion to form a base layer of a word line disposed on the control gates and on sections of the template, the base layer and the control gates forming a single homogenous structure without a deposition interface existing between the control gates and the base layer.

13. The method of claim 12, wherein the sacrificial layer comprises a carbon layer.

14. The method of claim 12, further comprising, before step (c):
providing an etch stop layer on top of the sacrificial layer, wherein an upper edge of the etch stop layer forms the upper edge of the sacrificial structures.

15. The method of claim 12, wherein step (d) further comprises:
depositing a template layer; and
removing portions of the template layer above the upper edge of the sacrificial structures to form the template.

16. The method of claim 12, further comprising, before step (d):
forming spacer structures extending along vertical sidewalls of the sacrificial structures.

17. The method of claim 16, wherein forming the spacer structures comprises:
depositing a conformal spacer layer; and
performing an anisotropical etch to form the spacer structures from the spacer layer.

18. The method of claim 16, further comprising, before step (d),
performing an implantation step to form buried bit lines in the semiconductor substrate and adjacent to the sacrificial structures, wherein the sacrificial structures and the spacer structures comprise an implantation mask.

19. The method of claim 8, wherein the template comprises a silicon oxide template.

20. The method of claim 12, wherein the gate electrodes are formed in a memory cell array section of the memory device, and CMOS gate electrodes are provided in a CMOS section of the memory device, the CMOS gate electrodes being formed, at least in part, contemporaneously with the control gates.

21. The method of claim 20, further comprising:
(h) removing word lines in a bit line contact section of the memory device to expose the template in the bit line contact section;
(i) providing a template spacer liner covering the template in the bit line contact section, the template spacer liner comprising a silicon oxide liner;
(j) providing a spacer mask on the template spacer liner, a first section of the spacer mask covering the bit line contact section and second sections extending along the vertical sidewalls of the CMOS gate electrodes;
(k) performing an implantation to form impurity regions in the CMOS section;
(l) removing the spacer mask;
(m) anisotropically etching the template spacer liner to form template spacer and to expose an upper edge of the template in the bit line contact section; and
(n) removing the template in the bit line contact section.

22. The method of claim 21, further comprising, before removing the template:
depositing an interlayer dielectric covering the memory cell array section; and
patterning the interlayer dielectric to expose the template and the template spacer in the bit line contact section.

23. The method of claim 21, wherein the template is removed with a fluid that dissolves the template spacer.

24. A method of forming a memory device, the method comprising:
(a) providing a substrate including a memory cell array section and a bit line contact section;
(b) providing memory cells in the memory cell array section, the memory cells being connected to bit lines buried in the substrate;
(c) providing temporary structures in the bit line contact section, the temporary structures being disposed above the semiconductor substrate and covering the buried bit lines;
(d) providing template spacers covering a vertical sidewall of each of the temporary structures; and
(e) removing the temporary structures using a fluid that dissolves the template spacers.

25. The method of claim 24, wherein the temporary structures comprise silicon oxide structures and the template spacers comprise silicon oxide spacers.

26. The method of claim 24, wherein providing the template spacers comprises:
providing a template spacer liner covering the temporary structures in the bit line contact section; and
anisotropically etching the template spacer liner to form the template spacers, wherein an upper edge of the temporary structures is exposed.

27. The method of claim 26, further comprising:
providing CMOS gate electrodes in a CMOS section of the memory device;
providing a spacer mask on the template spacer liner, a first section of the spacer mask covering the bit line contact section and second sections extending along vertical sidewalls of the CMOS gate electrodes;
performing an implantation to form impurity regions in the CMOS section; and
removing the spacer mask, wherein the template spacer liner provides an etch stop liner.

28. The method of claim 24, further comprising, before removing the temporary structures:
depositing an interlayer dielectric covering the memory cell array section; and
patterning the interlayer dielectric to expose the temporary structures in the bit line contact section.

29. A field effect transistor arrangement comprising:
gate electrodes arranged over a pattern surface of a semiconductor substrate, the gate electrodes comprising a gate conductor material; and
a connection line connecting the gate electrodes and comprising a base layer comprising the gate conductor material, the connection line including sections that are disposed on the gate electrodes and on an insulator structure separating the gate electrodes;
wherein the gate conductor material of the base layer and the gate electrodes forms a homogenous structure without a deposition interface existing between the gate electrodes and the base layer.

30. The field effect transistor arrangement of claim 29, wherein the gate conductor material comprises doped polycrystalline silicon.

31. The field effect transistor arrangement of claim 29, wherein the gate electrodes are arranged in a matrix including rows extending in a row direction and columns extending in a column direction intersecting the row direction, and the connection line connects gate electrodes that are arranged along the row direction.

32. A non-volatile memory device comprising:
control gates arranged over a pattern surface of a semiconductor substrate, the control gates comprising a gate conductor material; and
a word line connecting the control gates and comprising a base layer consisting of the gate conductor material, wherein the word line includes sections that are disposed on the control gates and on an insulator structure separating the control gates;
wherein the gate conductor material of the base layer and the control gates forms a homogenous structure without a deposition interface existing between the base layer and the control gates.

33. The memory device of claim 32, wherein the gate conductor material comprises doped polycrystalline silicon.

34. The memory device of claim 32, wherein the control gates are arranged in a matrix including rows extending in a row direction and columns extending in a column direction intersecting the row direction, and the word line connects control gates that are arranged along the row direction.
